(19) United States
(12) Patent Application Publication
(10) Pub. No.: US 2025/0331254 A1
(43) Pub. Date: Oct. 23, 2025

(54) SEMICONDUCTOR DEVICE AND METHOD FOR MANUFACTURING SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Akihiro IMADA, Yokohama (JP); Takahiro NAKAGAWA, Kawasaki (JP); Kazuya NISHIHORI, Tokyo (JP); Keita MASUDA, Kawasaki (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/830,990

(22) Filed: Sep. 11, 2024

(30) Foreign Application Priority Data
Apr. 18, 2024 (JP) 2024-067697

(51) Int. Cl. H01L 29/06; H01L 21/762

(52) U.S. Cl. CPC H10D 62/126; H01L 21/76267

(57) ABSTRACT

A method for manufacturing a semiconductor device includes forming an electrode on a structure body. The structure body includes a first insulating film, a second insulating film, and a semiconductor part. The electrode includes a first electrode part and a second electrode part. The first electrode part extends in a first direction and travers a region directly above the semiconductor part. The second electrode part extends from the first electrode part in a second direction. The method includes forming a first semiconductor part. The method includes forming a first mask on the structure body. The method includes forming a second semiconductor part in a portion of the first semiconductor part by using the first mask and the electrode as a mask to ion-implant an impurity. The method includes removing the first mask. The method includes forming a contact connected to the one part.

### CROSS-REFERENCE TO RELATED APPLICATIONS

This application is based upon and claims the benefit of priority from Japanese Patent Application No. 2024-067697, filed on Apr. 18, 2024; the entire contents of which are incorporated herein by reference.

### FIELD

Embodiments described herein relate generally to a semiconductor device and a method for manufacturing a semiconductor device.

### BACKGROUND

Known technology for increasing the operation speed of a semiconductor device included in a logic circuit includes forming a MOSFET (Metal-Oxide-Semiconductor Field-Effect Transistor) in an SOI (Silicon On Insulator) substrate. However, a MOSFET that is formed in an SOI substrate is problematic in that the operations are difficult to stabilize.

### BRIEF DESCRIPTION OF THE DRAWINGS

FIG. 1 is a plan view showing a semiconductor device according to an embodiment;

FIG. 2 is a plan view showing a silicon part and a STI of the semiconductor device according to the embodiment;

FIG. 3 is a cross-sectional view along line A-A′ shown in FIG. 1;

FIG. 4 is a cross-sectional view along line B-B′ shown in FIG. 1;

FIG. 5 is a plan view showing a method for manufacturing the semiconductor device according to the embodiment;

FIG. 6 is a cross-sectional view along line A-A′ shown in FIG. 5;

FIG. 7 is a cross-sectional view along line B-B′ shown in FIG. 5;

FIG. 8 is a plan view showing the method for manufacturing the semiconductor device according to the embodiment;

FIG. 9 is a cross-sectional view along line A-A′ shown in FIG. 8;

FIG. 10 is a cross-sectional view along line B-B′ shown in FIG. 8;

FIG. 11 is a plan view showing the method for manufacturing the semiconductor device according to the embodiment;

FIG. 12 is a cross-sectional view along line A-A′ shown in FIG. 11;

FIG. 13 is a cross-sectional view along line B-B′ shown in FIG. 11;

FIG. 14 is a plan view showing the method for manufacturing the semiconductor device according to the embodiment;

FIG. 15 is a cross-sectional view along line A-A′ shown in FIG. 14;

FIG. 16 is a cross-sectional view along line B-B′ shown in FIG. 14;

FIG. 17 is a plan view showing a method for manufacturing a semiconductor device according to a comparative example;

FIG. 18 is a cross-sectional view along line A-A′ shown in FIG. 17; and

FIG. 19 is a cross-sectional view along line B-B′ shown in FIG. 17.

### DETAILED DESCRIPTION

In general, according to one embodiment, a method for manufacturing a semiconductor device includes forming an electrode on a structure body. The structure body includes a first insulating film, a second insulating film located on the first insulating film, and a semiconductor part located on the first insulating film, the semiconductor part being surrounded with the second insulating film. The electrode includes a first electrode part and a second electrode part. The first electrode part extends in a first direction and travers a region directly above the semiconductor part. The second electrode part extends from the first electrode part in a second direction. The second direction crosses the first direction. The method includes forming a first semiconductor part in a part of the semiconductor part not covered with the electrode and in a part of the semiconductor part that is covered with the electrode and contacts the part of the semiconductor part not covered with the electrode. The first semiconductor part is of a first conductivity type. The forming of the first semiconductor part includes using the electrode as a mask to ion-implant an impurity from a direction tilted with respect to a third direction. The third direction is orthogonal to the first and second directions. The method includes forming a first mask on the structure body. The first mask covers one part of the semiconductor part. The one part is not covered with the electrode. The one part contacts a part of the semiconductor part covered with the second electrode part. The method includes forming a second semiconductor part in a portion of the first semiconductor part by using the first mask and the electrode as a mask to ion-implant an impurity. The second semiconductor part is of a second conductivity type. The method includes removing the first mask. The method includes forming a contact connected to the one part.

In general, according to one embodiment, a semiconductor device includes a first insulating film, a first semiconductor part located on the first insulating film, a second semiconductor part located on the first insulating film, a third semiconductor part located on the first insulating film, a second insulating film located on the first insulating film, an electrode, and a contact connected to the third semiconductor part. The first semiconductor part is of a first conductivity type. The first semiconductor part includes a first part extending in a first direction, and a second part extending from the first part in a second direction. The second direction crosses the first direction. The second semiconductor part is of a second conductivity type. The second semiconductor part contacts the first semiconductor part. The second semiconductor part is partitioned into two regions by the first semiconductor part. The third semiconductor part is of the first conductivity type. The third semiconductor part has a higher effective impurity concentration than the first semiconductor part. The third semiconductor part contacts the second part of the first semiconductor part. The third semiconductor part is separated from the first part of the first semiconductor part. The second insulating film surrounds a semiconductor part when viewed from above. The semiconductor part includes the first, second, and third semiconductor parts. The electrode includes a first electrode part located in a region directly above the first part, and a second electrode part located in a region directly above the second part.

### Embodiment

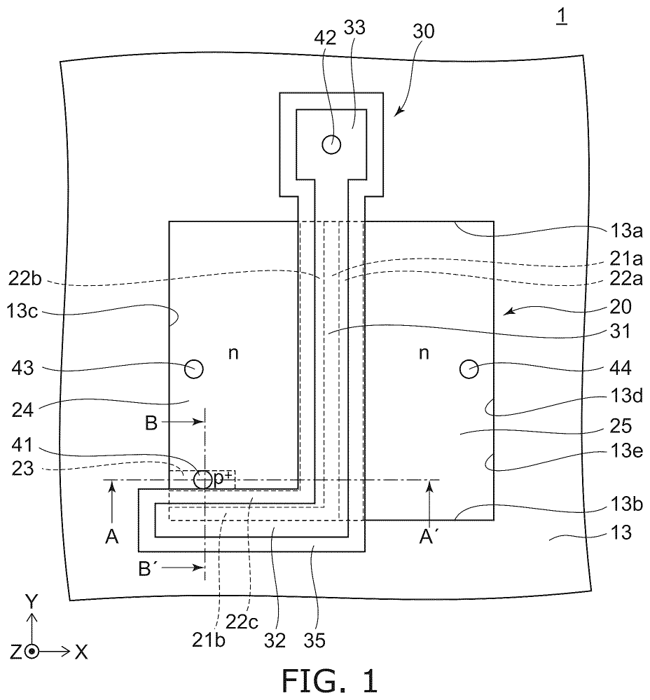

FIG. 1 is a plan view showing a semiconductor device according to the embodiment.

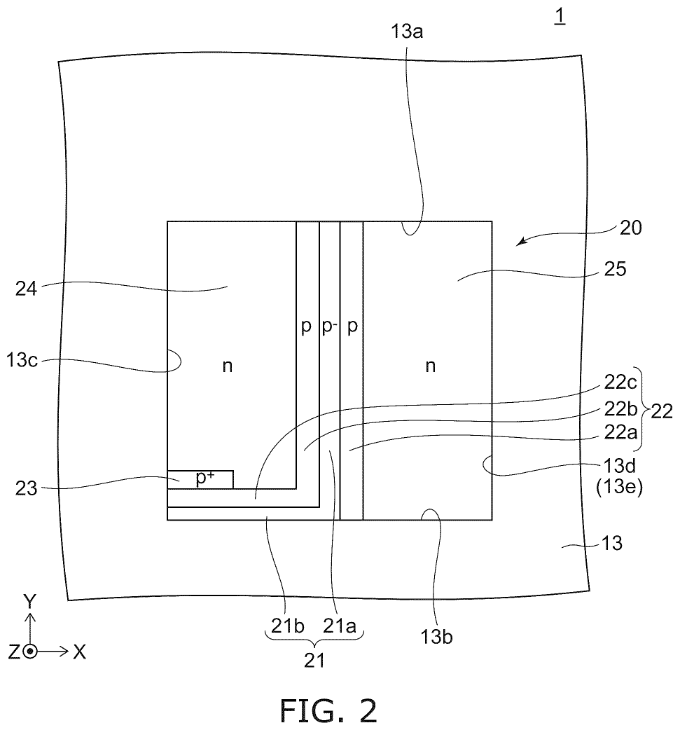

FIG. 2 is a plan view showing a silicon part and a STI of the semiconductor device according to the embodiment.

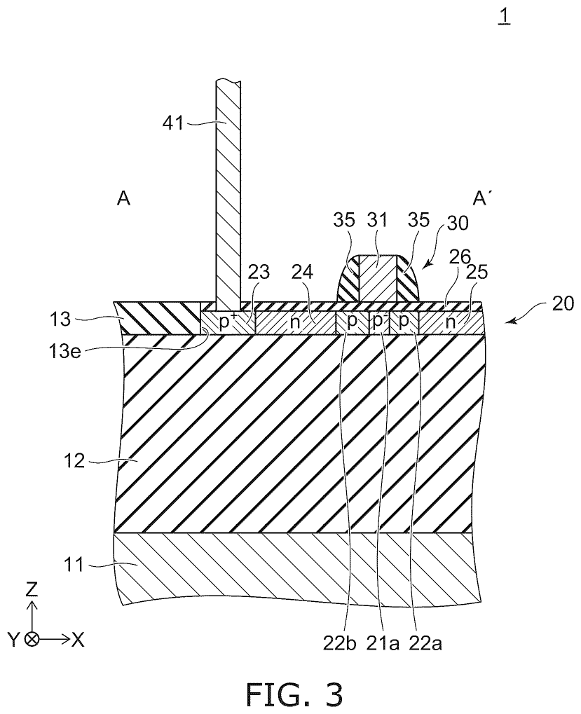

FIG. 3 is a cross-sectional view along line A-A′ shown in FIG. 1.

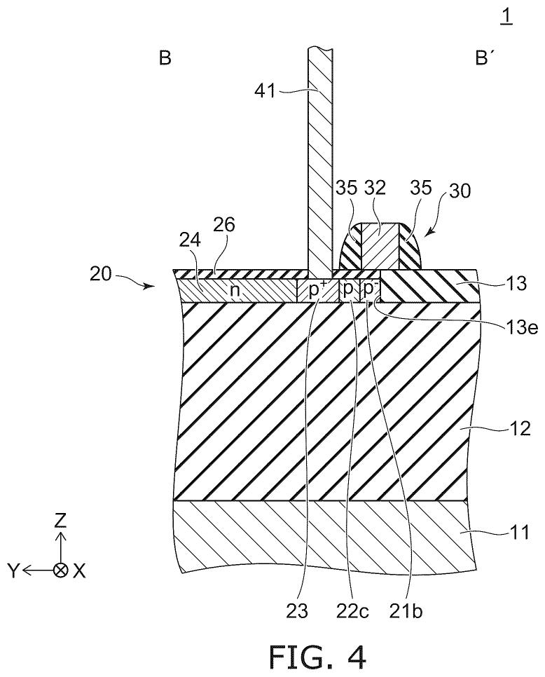

FIG. 4 is a cross-sectional view along line B-B′ shown in FIG. 1.

As shown in FIGS. 1 to 4, the semiconductor device 1 according to the embodiment includes a silicon substrate 11, a BOX film 12, a STI (Shallow Trench Isolation; element-separation insulating film) 13, a silicon part 20, a gate electrode 30, and contacts 41 to 44.

The silicon substrate 11 is made of, for example, a semiconductor material, and is made of, for example, single-crystal silicon (Si). The BOX film 12 and the STI 13 are made of insulating materials, and are made of, for example, silicon oxide (SiO₂). The silicon part 20 is made of, for example, a semiconductor material, and is made of, for example, silicon. The BOX film 12 is located on the silicon substrate 11. The STI 13 and the silicon part 20 are located on the BOX film 12. The gate electrode 30 and the contacts 41 to 44 are located on the STI 13 and on the silicon part 20.

An opening 13e is formed in the STI 13; and the silicon part 20 is located inside the opening 13e. Therefore, when viewed from above, the silicon part 20 is surrounded with the STI 13 and partitioned from the periphery by the BOX film 12 and the STI 13. Although the semiconductor device 1 may include multiple silicon parts 20, only one silicon part 20 is described in 10 the embodiment.

In the specification, an XYZ orthogonal coordinate system is employed for convenience of description. The direction from the silicon substrate 11 toward the BOX film 12 is taken as a “Z-direction”; and two mutually-orthogonal directions that are orthogonal to the Z-direction are taken as an “X-direction” and a “Y-direction”. The X-direction is differentiated as the “+X direction” and the “−X direction” as necessary. This is similar for the Y-direction and the Z-direction. Although the +Z direction also is called “up/above”, and the −Z direction also is called “down/below”, these expressions are for convenience and are independent of the direction of gravity. In the specification, “connected” means an electrical connection.

When viewed along the Z-direction, the opening 13e of the STI 13 is, for example, rectangular. Accordingly, when viewed along the Z-direction, the silicon part 20 also is, for example, rectangular. The inner edge of the opening 13e is made of a pair of sides 13a and 13b extending in the X-direction, and a pair of sides 13c and 13d extending in the Y-direction.

Portions of the silicon part 20 are made into semiconductors of p- or n-conductivity types by introducing impurities. The silicon part 20 includes a channel region 21 of the p-conductivity type, a halo region 22 of the p-conductivity type, a body contact region 23 of the p⁺-conductivity type, a source region 24 of the n-conductivity type, and a drain region 25 of the n-conductivity type. The effective impurity concentration of the body contact region 23 is greater than the effective impurity concentration of the halo region 22. The effective impurity concentration of the halo region 22 is greater than the effective impurity concentration of the channel region 21.

“Effective impurity concentration” refers to the concentration of the impurity contributing to the conduction of the semiconductor, and refers to the net impurity concentration excluding the cancelled portion when both an impurity that forms acceptors and an impurity that forms donors are included in a part.

The channel region 21 includes a part 21a that extends in the Y-direction from the X-direction central portion of the side 13a of the STI 13 to reach the X-direction central portion of the side 13b of the STI 13, and a part 21b that extends toward one side in the X-direction (the −X direction side) and extends from the part 21a along the side 13b of the STI 13 to reach the side 13c.

The halo region 22 includes a part 22a that is located at the +X direction side of the part 21a of the channel region 21 and contacts the part 21a, a part 22b that is located at the −X direction side of the part 21a and contacts the part 21a, and a part 22c that is located at the +Y direction side of the part 21b of the channel region 21 and contacts the part 21b. The part 22a and the part 22b extend in the Y-direction. The part 22c extends in the −X direction from the end portion of the part 22b at the −Y direction side, extends in the −X direction along the part 21b of the channel region 21, and reaches the side 13c of the STI 13. The part 22b and the part 22c of the halo region 22 are formed to be continuous. The part 22a is separated from the parts 22b and 22c via the part 21a of the channel region 21.

The body contact region 23 contacts the part 22c of the halo region 22 and the side 13c of the STI 13 and is separated from the entire channel region 21 and the parts 22a and 22b of the halo region 22. When viewed from above, the body contact region 23 is, for example, rectangular. As described above, the body contact region 23 contacts the part 22c of the halo region 22; and the part 22b of the halo region 22 contacts the channel region 21; therefore, the body contact region 23 is connected to the channel region 21 via the halo region 22.

The source region 24 is positioned at the −X direction side of the part 22b of the halo region 22, and contacts the parts 22b and 22c of the halo region 22, the body contact region 23, and the sides 13a and 13c of the STI 13. The drain region 25 is positioned at the +X direction side of the part 22a of the halo region 22, and contacts the part 22a of the halo region 22 and the side 13a, side 13b, and side 13d of the STI 13.

The part 21a of the channel region 21 is located between the source region 24 and the drain region 25. The part 22b of the halo region 22 is located between the source region 24 and the part 21a. The part 22a of the halo region 22 is located between the drain region 25 and the part 21a. The source region 24 and the drain region 25 are partitioned by the part 21a of the channel region 21 and the parts 22a and 22b of the halo region 22.

In the Y-direction central portion of the silicon part 20, the source region 24, the part 22b of the halo region 22, the part 21a of the channel region 21, the part 22a of the halo region 22, and the drain region 25 are arranged in this order from the side 13c toward the side 13d of the STI 13. The part 21b of the channel region 21, the part 22c of the halo region 22, and the body contact region 23 are located at the −Y direction side of the source region 24 side when viewed from the part 21a of the channel region 21.

The gate electrode 30 includes a first electrode part 31, a second electrode part 32, a pad part 33, and a sidewall 35. When viewed along the Z-direction, the pad part 33 is located outside the opening 13e of the STI 13 at the +Y direction side of the silicon part 20. The first electrode part 31 extends from the pad part 33 to the −Y direction side, and traverses a region directly above the silicon part 20. The second electrode part 32 extends from the end portion of the first electrode part 31 at the −Y direction side to the −X direction side, and extends along a region directly above the side 13b of the STI 13. The pad part 33, the first electrode part 31, and the second electrode part 32 are formed as a continuous body from a conductive material such as, for example, polysilicon including an impurity. The sidewall 35 is insulative and is located at the periphery of the conductive part that includes the first electrode part 31, the second electrode part 32, and the pad part 33 when viewed along the Z-direction.

A gate insulating film 26 is located between the silicon part 20 and the gate electrode 30. Therefore, the gate electrode 30 is insulated from the silicon part 20. For example, the gate insulating film 26 is formed of silicon oxide. The gate insulating film 26 is not illustrated in FIGS. 1 and 2. This is similar for the other plan views below as well.

The part 21a of the channel region 21 and the parts 22a and 22b of the halo region 22 are located in the region directly under the first electrode part 31 of the gate electrode 30. The part 21b of the channel region 21 and the part 22c of the halo region 22 are located in the region directly under the second electrode part 32. The body contact region 23, the source region 24, and the drain region 25 are not located in the region directly under the gate electrode 30.

An inter-layer insulating film (not illustrated) is located above the STI 13, the gate insulating film 26, the gate electrode 30, and the sidewall 35; and the contacts 41 to 44 are located inside the inter-layer insulating film. The lower end of the contact 41 is connected to the body contact region 23 of the silicon part 20. The lower end of the contact 42 is connected to the pad part 33 of the gate electrode 30. The lower end of the contact 43 is connected to the source region 24. The lower end of the contact 44 is connected to the drain region 25. n⁺-type contact layers may be formed at the parts of the source region 24 and the drain region 25 that contact the contacts 43 and 44.

A method for manufacturing the semiconductor device according to the embodiment will now be described.

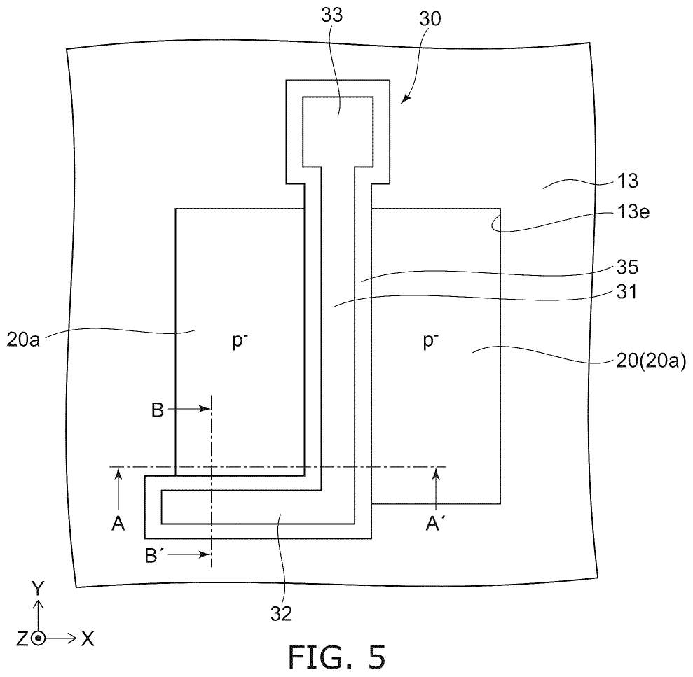

FIG. 5 is a plan view showing the method for manufacturing the semiconductor device according to the embodiment.

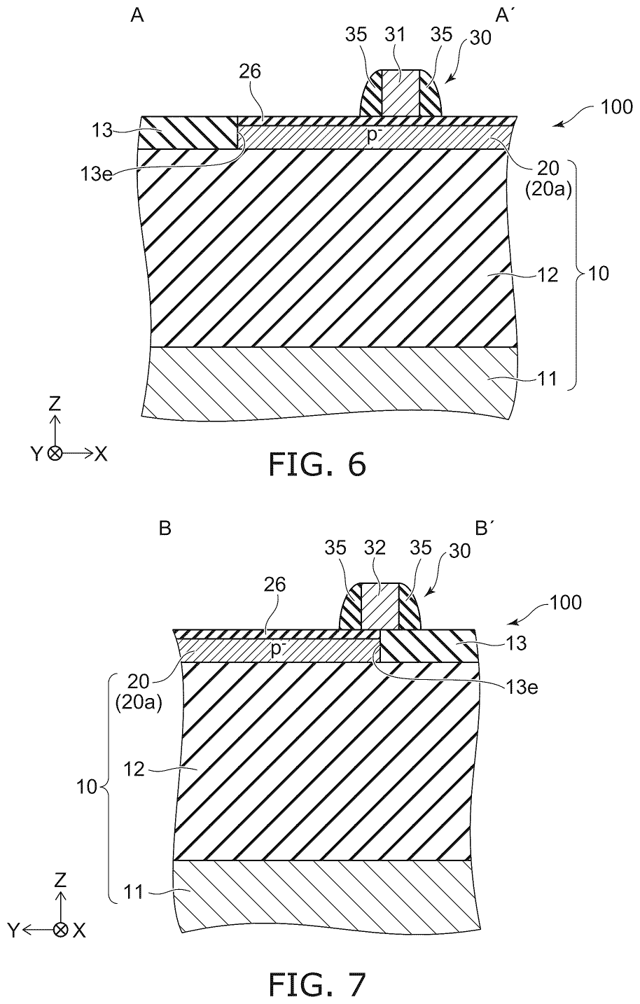

FIG. 6 is a cross-sectional view along line A-A′ shown in FIG. 5.

FIG. 7 is a cross-sectional view along line B-B′ shown in FIG. 5.

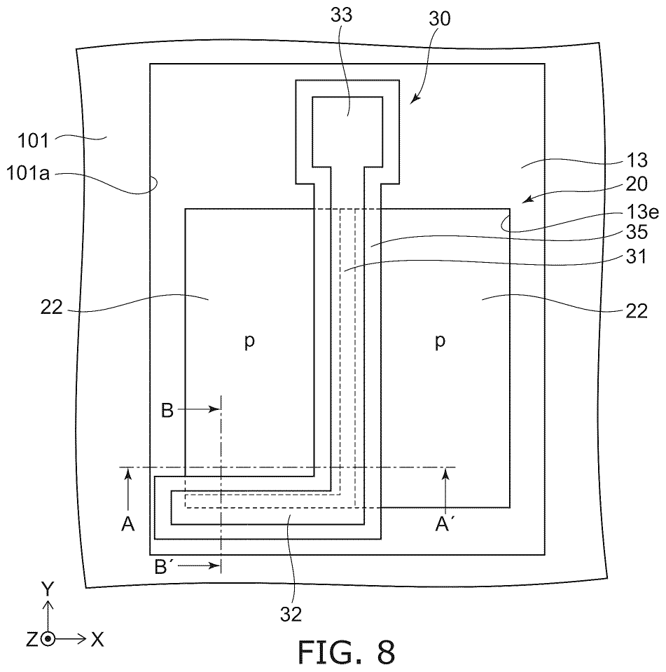

FIG. 8 is a plan view showing the method for manufacturing the semiconductor device according to the embodiment.

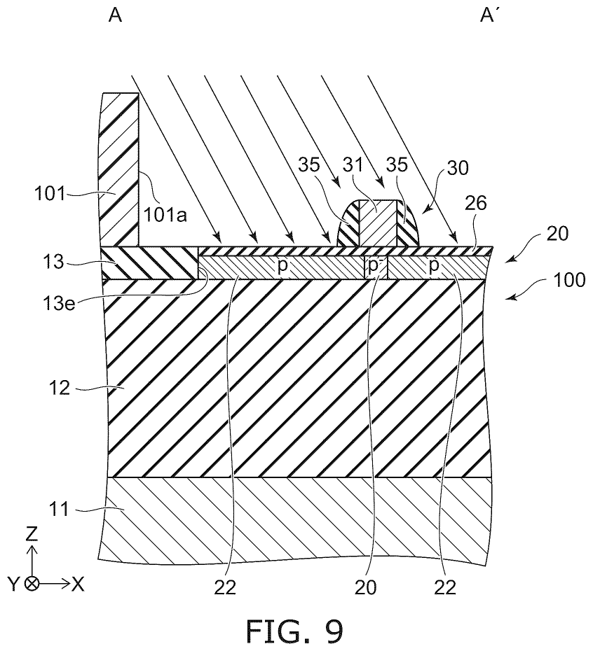

FIG. 9 is a cross-sectional view along line A-A′ shown in FIG. 8.

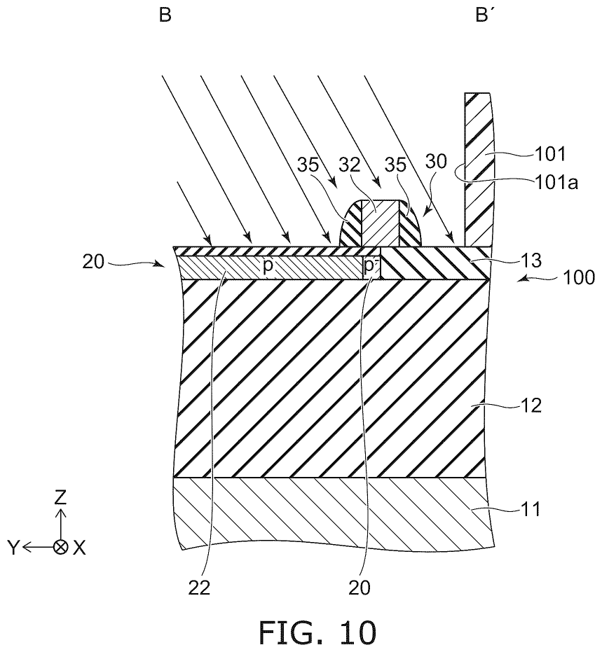

FIG. 10 is a cross-sectional view along line B-B′ shown in FIG. 8.

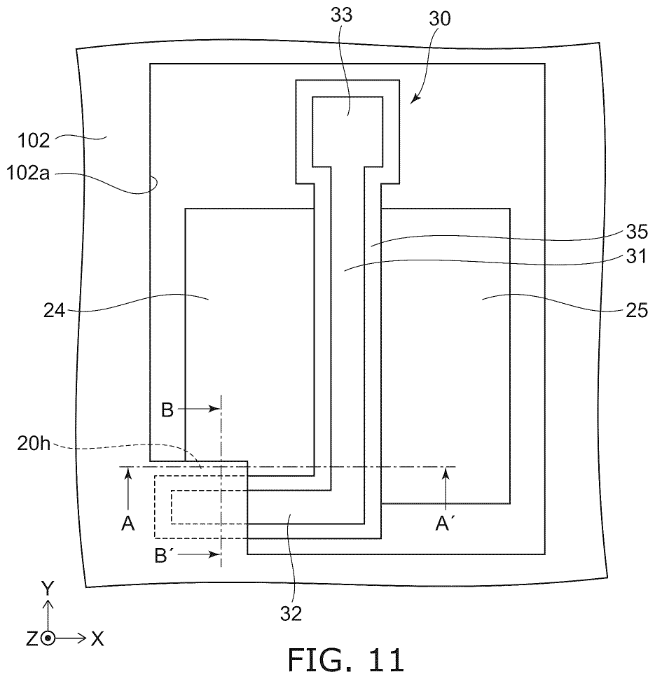

FIG. 11 is a plan view showing the method for manufacturing the semiconductor device according to the embodiment.

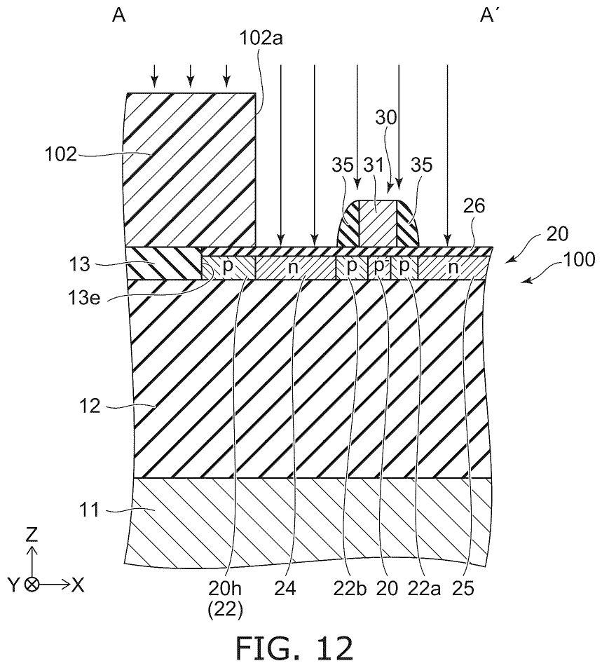

FIG. 12 is a cross-sectional view along line A-A′ shown in FIG. 11.

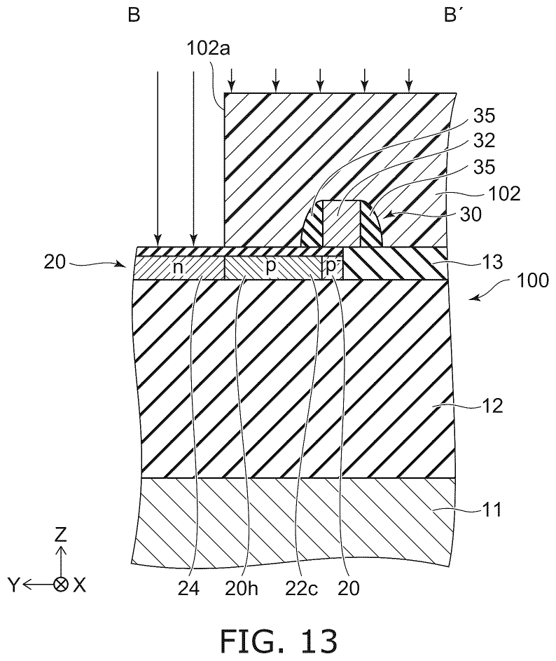

FIG. 13 is a cross-sectional view along line B-B′ shown in FIG. 11.

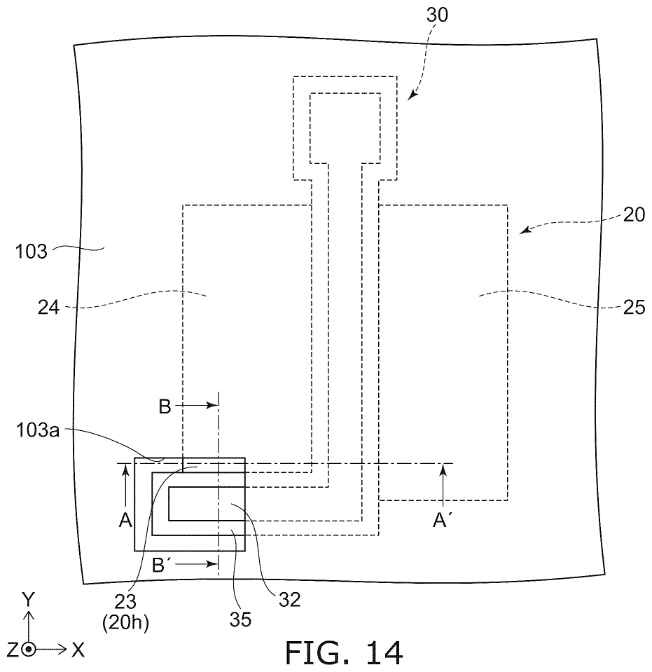

FIG. 14 is a plan view showing the method for manufacturing the semiconductor device according to the embodiment.

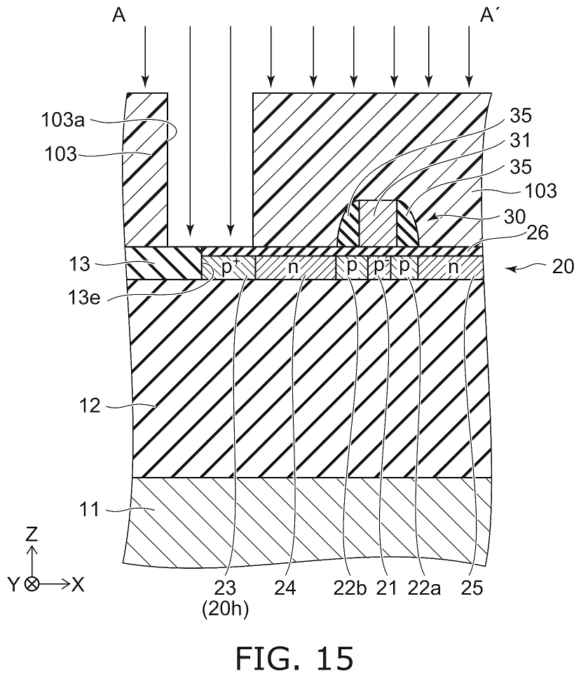

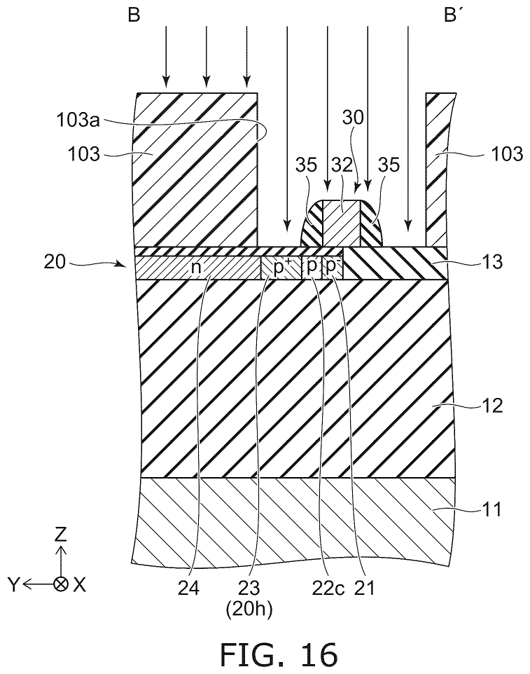

FIG. 15 is a cross-sectional view along line A-A′ shown in FIG. 14.

FIG. 16 is a cross-sectional view along line B-B′ shown in FIG. 14.

First, an SOI substrate 10 is prepared as shown in FIGS. 5 to 7. The silicon substrate 11, the BOX film 12, and a silicon layer 20a are stacked in this order in the SOI substrate 10. The conductivity type of the silicon layer 20a is the p⁻-type.

Then, the STI 13 is formed by selective thermal oxidation of the silicon layer 20a. At this time, the lower surface of the STI 13 contacts the upper surface of the BOX film 12. The unoxidized part of the silicon layer 20a becomes the silicon part 20, and is located inside the opening 13e of the STI 13. Thus, a structure body 100 is formed.

Continuing, the gate insulating film 26 is formed at the upper surface of the silicon part 20. Then, the pad part 33, the first electrode part 31 that extends in the Y-direction, and the second electrode part 32 that extends in the −X direction from the first electrode part 31 are formed as a continuous body on the gate insulating film 26. Then, the insulating sidewall 35 is formed on the side surfaces of the pad part 33, the first electrode part 31, and the second electrode part 32. Thus, the gate electrode 30 is formed on the structure body 100. In the following description, the “structure body 100” includes the gate insulating film 26 and the gate electrode 30. The “gate electrode 30” includes the sidewall 35.

Then, as shown in FIGS. 8 to 10, a mask 101 (a third mask) is formed on the structure body 100. For example, the mask 101 is formed by exposing and developing a resist. An opening 101a is formed in the mask 101. The silicon part 20 and the part of the STI 13 positioned at the periphery of the opening 13e are exposed inside the opening 101a. The part of the silicon part 20 positioned in the region directly under the gate electrode 30 is covered with the gate electrode 30, but the other part of the silicon part 20 is not covered with the gate electrode 30 or the mask 101.

Continuing, an impurity is implanted from a direction tilted with respect to the Z-direction by using the mask 101 and the gate electrode 30 as a mask. For example, an impurity that forms acceptors such as, for example, boron (B) is ion-implanted four times from a total of four directions, i.e., a direction tilted 30° in the −X direction with respect to the Z-direction, a direction tilted 30° in the +X direction with respect to the Z-direction, a direction tilted 30° in the −Y direction with respect to the Z-direction, and a direction tilted 30° in the +Y direction with respect to the Z-direction. The dose at this time is set to, for example, 10¹² cm⁻². By implanting the impurity from directions tilted with respect to the Z-direction, the impurity is implanted not only into the part of the silicon part 20 not covered with the gate electrode 30, but also into a portion of the part of the silicon part 20 covered with the gate electrode 30.

As a result, the halo region 22 of the p-conductivity type is formed in the part of the silicon part 20 not covered with the gate electrode 30, and in a portion of the part of the silicon part 20 covered with the gate electrode 30 that contacts the part of the silicon part 20 not covered with the gate electrode 30. Subsequently, the mask 101 is removed.

Then, as shown in FIGS. 11 to 13, a mask 102 (a first mask) is formed on the structure body 100. For example, the mask 102 is formed by exposing and developing a resist. An opening 102a is formed in the mask 102. The mask 102 covers a part 20h of the silicon part 20 located at the corner part at the −X direction side and the −Y direction side, and does not cover the part of the silicon part 20 other than the part 20h. In this process, the part 20h is a portion of the halo region 22, and is the part at which the body contact region 23 will be formed in a subsequent process. The part 20h is not covered with the gate electrode 30, and contacts the part of the silicon part 20 covered with the gate electrode 30.

Continuing, an impurity is implanted by using the mask 102 and the gate electrode 30 as a mask. An impurity that forms donors such as, for example, phosphorus (P) is ion-implanted from, for example, the Z-direction. At this time, for example, the dose is set to 10¹³ to 10¹⁴ cm⁻². As a result, the regions of the halo region 22 that are not covered with the mask 102 or the gate electrode 30 become the n-type source region 24 and the n-type drain region 25. The part of the remaining halo region 22 covered with the first electrode part 31 becomes the parts 22a and 22b; and the part of the remaining halo region 22 covered with the second electrode part 32 becomes the part 22c. The impurity that forms donors is not implanted into the part 20h in this process. Subsequently, the mask 102 is removed.

Then, as shown in FIGS. 14 to 16, a mask 103 (a second mask) is formed on the structure body 100. For example, the mask 103 is formed by exposing and developing a resist. An opening 103a is formed in the mask 103. The part 20h of the silicon part 20 is exposed inside the opening 103a. The mask 103 and the gate electrode 30 cover the part of the silicon part 20 other than the part 20h.

Continuing, an impurity is implanted by using the mask 103 and the gate electrode 30 as a mask. An impurity that forms acceptors such as, for example, boron is ion-implanted from, for example, the Z-direction. At this time, the dose is set to, for example, 10¹⁵ cm⁻². As a result, the part 20h changes from the p-type halo region 22 to the p⁺-type body contact region 23. As a result, the body contact region 23 contacts the part 22c of the halo region 22 positioned in the region directly under the second electrode part 32.

Subsequently, the mask 103 is removed. The region of the silicon part 20 in which the halo region 22, the source region 24, the drain region 25, and the body contact region 23 are not formed becomes the p-type channel region 21.

Then, as shown in FIGS. 1 to 4, for example, the impurities that are implanted into each portion are activated by performing heat processing. An inter-layer insulating film (not illustrated) is formed on the structure body 100; and the contacts 41 to 44 are formed inside the inter-layer insulating film. The lower end of the contact 41 connects the body contact region 23; the lower end of the contact 42 connects the pad part 33 of the gate electrode 30; the lower end of the contact 43 connects the source region 24; and the lower end of the contact 44 connects the drain region 25. Thus, the semiconductor device 1 is manufactured.

In the semiconductor device 1, a ground potential is applied to the halo region 22 and the channel region 21 via the contact 41 and the body contact region 23; the ground potential is applied to the source region 24 via the contact 43; and a positive power supply potential is applied to the drain region 25 via the contact 44. The source region 24 and the drain region 25 conduct when a potential that is not less than a threshold is applied to the gate electrode 30 via the contact 42 in this state; and the source region 24 and the drain region 25 do not conduct when a potential that is less than the threshold is applied to the gate electrode 30. At this time, the operations of the semiconductor device 1 are stable because the potentials of the halo region 22 and the channel region 21 are fixed to the ground potential.

Effects of the embodiment will now be described.

According to the embodiment as shown in FIGS. 8 to 10, the part 20h at which the body contact region 23 will be formed is not covered with the mask 101 when forming the halo region 22. The impurity that forms acceptors is ion-implanted from a direction tilted with respect to the Z-direction. As a result, the halo region 22 is formed also in a part that is covered with the gate electrode 30 and contacts the part 20h.

Then, as shown in FIGS. 11 to 13, the part 20h is covered with the mask 102 when forming the source region 24 and the drain region 25. The impurity that forms donors is ion-implanted from the Z-direction. As a result, the impurity that forms donors is not implanted into the part 20h. Then, as shown in FIGS. 14 to 16, the body contact region 23 is formed by using the mask 103 that does not cover the part 20h.

As a result, the body contact region 23 contacts the part 22c of the halo region 22, and so a continuous current path can be formed from the body contact region 23 to the channel region 21. Thus, according to the embodiment, the halo region 22 can be formed in the part of the silicon part 20 covered with the gate electrode 30; and the body contact region 23 can be connected to the channel region 21 via this part. As a result, the potential of the channel region 21 can be stabilized, and the operations of the semiconductor device 1 can be stabilized.

By separating the body contact region 23 from the part 22b of the halo region 22, the gate width at the source region 24 side and the gate width at the drain region 25 side can be equal, and the source-drain symmetry can be ensured.

By using different masks for the masks 101 and 102, shadowing of the mask 101 and the electrode 30 can be suppressed while separating the body contact region 23 from the part 22b of the halo region 22; and the distance between the body contact region 23 and the part 22b can be reduced. As a result, the semiconductor device 1 can be smaller.

### Comparative Example

According to a comparative example, a common mask 110 is used instead of the masks 101 and 102 according to the embodiment above.

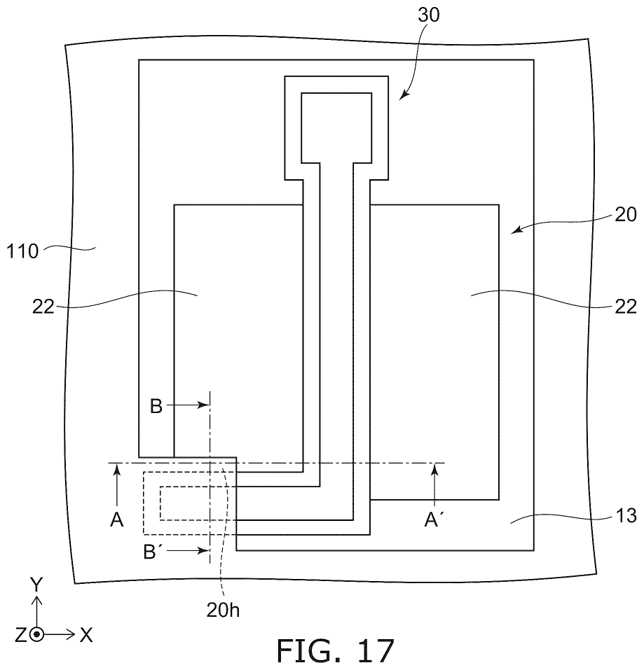

FIG. 17 is a plan view showing a method for manufacturing a semiconductor device according to the comparative example.

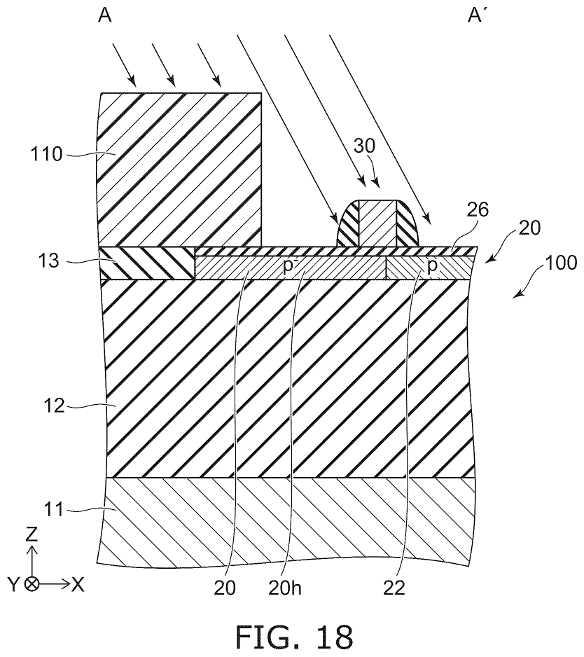

FIG. 18 is a cross-sectional view along line A-A′ shown in FIG. 17.

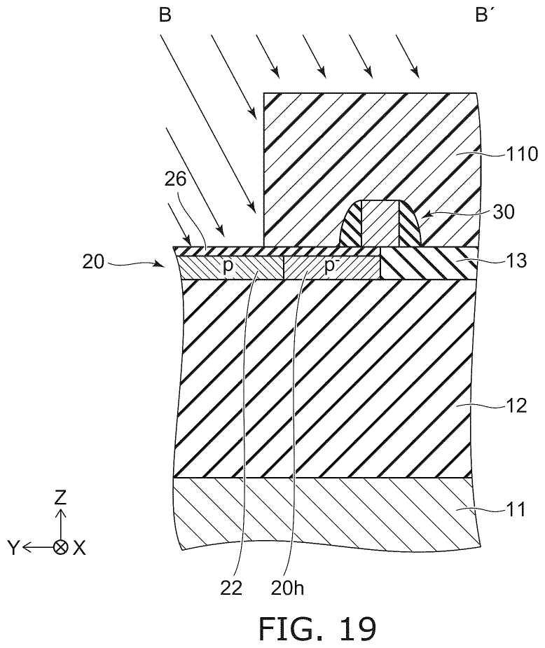

FIG. 19 is a cross-sectional view along line B-B′ shown in FIG. 17.

First, the processes shown in FIGS. 5 to 7 are performed.

Then, as shown in FIGS. 17 to 19, a mask 110 is formed on the structure body 100. The shape of the mask 110 is similar to that of the mask 102 shown in FIGS. 11 to 13. Then, an impurity is ion-implanted from a direction tilted with respect to the Z-direction by using the mask 110 and the gate electrode 30 as a mask.

At this time, the part 20h of the silicon part 20 is covered with the mask 110, and so the periphery of the part 20h is in the shadow of the mask 110 when implanting the impurity; and the implantation of the impurity is obstructed. In other words, shadowing that is caused by the mask 110 occurs. As a result, the halo region 22 is not formed in the part of the silicon part 20 that is covered with the gate electrode 30 and contacts the part 20h.

Then, a process similar to the process shown in FIGS. 11 to 13 are performed. However, the mask 110 continues to be used instead of the mask 102. In other words, the source region 24 and the drain region 25 are formed by implanting an impurity by using the mask 110 and the gate electrode 30 as a mask. At this time, the impurity is not implanted into the part 20h.

Continuing, a process similar to the process shown in FIGS. 14 to 16 are performed. In other words, the body contact region 23 is formed in the part 20h by implanting an impurity by using the mask 103 and the gate electrode 30 as a mask. Thereafter, the processes are similar to those of the embodiment above.

According to the comparative example, the halo region 22 is not formed in the part of the silicon part 20 contacting the part 20h in the process shown in FIGS. 17 to 19. Therefore, after the body contact region 23 is formed in the part 20h, the body contact region 23 substantially does not contact the halo region 22, and so a current path is not stably formed from the contact 41 to the channel region 21. As a result, the operations of the semiconductor device are not stabilized.

According to the embodiments above, a semiconductor device and a method for manufacturing a semiconductor device can be realized in which the operations can be stabilized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the second electrode part 32 of the gate electrode 30 may be located in the region directly above the side 13a of the STI 13. In other words, the second electrode part 32 may be located between the pad part 33 and the first electrode part 31 in the Y-direction. In such a case as well, the part 21b of the channel region 21 and the part 22c of the halo region 22 are located in the region directly under the second electrode part 32; and the body contact region 23 is located at a position contacting the part 22c. Also, the conductivity types of the portions described above may be reversed.

Embodiments include the following aspects.

### Note 1

A method for manufacturing a semiconductor device, the method comprising:
forming an electrode on a structure body, the structure body including a first insulating film, a second insulating film located on the first insulating film, and a semiconductor part located on the first insulating film, the semiconductor part being surrounded with the second insulating film, the electrode including a first electrode part, a second electrode part and a sidewall, the first electrode part extending in a first direction and traversing a region directly above the semiconductor part, the second electrode part extending from the first electrode part in a second direction, the second direction crossing the first direction, the sidewall being insulative and being located at a periphery of a conductive part that includes the first electrode part and the second electrode part when viewed along a third direction, the first direction and the second direction being parallel to an upper surface of the semiconductor part, the third direction being orthogonal to the first and second directions;
forming a first semiconductor part in a part of the semiconductor part not covered with the electrode and in a part of the semiconductor part that is covered with the electrode and contacts the part of the semiconductor part not covered with the electrode, the first semiconductor part being of a first conductivity type, the forming of the first semiconductor part including using the electrode as a mask to ion-implant an impurity from a direction tilted with respect to the third direction;
forming a first mask on the structure body, the first mask covering one part of the first semiconductor part, the one part not being covered with the electrode, the one part contacting a part of the semiconductor part covered with the second electrode part;
forming a second semiconductor part in a portion of the first semiconductor part by using the first mask and the electrode as a mask to ion-implant an impurity, the second semiconductor part being of a second conductivity type;
removing the first mask; and
forming a contact connected to the one part.

### Note 2

The method according to note 1, further comprising, after the removing of the first mask, and before the forming of the contact:
forming a second mask on the structure body, the second mask covering the second semiconductor part, the second mask not covering the one part; and
forming a third semiconductor part in the one part by using the second mask and the electrode as a mask to ion-implant an impurity, the third semiconductor part being of the first conductivity type, the third semiconductor part having a higher effective impurity concentration than the first semiconductor part.

### Note 3

The method according to note 2, wherein
the third semiconductor part contacts a part of the first semiconductor part positioned in a region directly under the sidewall, and
the third semiconductor part is separated from a part of the first semiconductor part positioned in a region directly under the first electrode part.

### Note 4

The method according to any one of notes 1-3, further comprising:
after the forming of the electrode and before the forming of the first semiconductor part, forming a third mask on the structure body, the third mask not covering the semiconductor part; and
removing the third mask after the forming of the first semiconductor part and before the forming of the first mask,
the third mask also being used as the mask used in the forming of the first semiconductor part.

### Note 5

The method according to any one of notes 1-4, wherein
the semiconductor part is of the first conductivity type when the forming of the electrode is performed.

### Note 6

The method according to any one of notes 1-5, wherein
the second semiconductor part is partitioned into two regions by a part of the first semiconductor part positioned in the region directly under the first electrode part.

### Note 7

The method according to note 6, wherein
the electrode is a gate electrode,
the two regions are a source region and a drain region, and
the second electrode part is located at the source region side.

### Note 8

A semiconductor device, comprising:
a first insulating film;
a first semiconductor part located on the first insulating film, the first semiconductor part being of a first conductivity type, the first semiconductor part including
   a first part extending in a first direction, and
   a second part extending from the first part in a second direction, the second direction crossing the first direction;
a second semiconductor part located on the first insulating film, the second semiconductor part being of a second conductivity type, the second semiconductor part contacting the first semiconductor part, the second semiconductor part being partitioned into two regions by the first semiconductor part;
a third semiconductor part located on the first insulating film, the third semiconductor part being of the first conductivity type, the third semiconductor part having a higher effective impurity concentration than the first semiconductor part, the third semiconductor part contacting the second part of the first semiconductor part, the third semiconductor part being separated from the first part of the first semiconductor part;
a second insulating film located on the first insulating film, the second insulating film surrounding a semiconductor part when viewed from above, the semiconductor part including the first, second, and third semiconductor parts;
an electrode including
   a first electrode part located in a region directly above the first part,
   a second electrode part, and
   a sidewall located in a region directly above the second part, the sidewall being insulative and being located at a periphery of a conductive part that includes the first electrode part and the second electrode part when viewed along a third direction, the third direction being orthogonal to the first and second directions; and
a contact connected to the third semiconductor part.

### Note 9

The device according to note 8, wherein
the electrode is a gate electrode,
the two regions are a source region and a drain region, and
the third semiconductor part is located at the source region side and contacts the source region.

### Note 10

The device according to note 8 or 9, wherein
the first conductivity type is a p-type, and
the second conductivity type is an n-type.

### Note 11

The device according to any one of notes 8-10, further comprising:
a semiconductor substrate,
the first insulating film being located on the semiconductor substrate.

What is claimed is:

1. A method for manufacturing a semiconductor device, the method comprising:
forming an electrode on a structure body, the structure body including a first insulating film, a second insulating film located on the first insulating film, and a semiconductor part located on the first insulating film, the semiconductor part being surrounded with the second insulating film, the electrode including a first electrode part, a second electrode part and a sidewall, the first electrode part extending in a first direction and traversing a region directly above the semiconductor part, the second electrode part extending from the first electrode part in a second direction, the second direction crossing the first direction, the sidewall being insulative and being located at a periphery of a conductive part that includes the first electrode par and the second electrode part when viewed along a third direction, the first direction and the second direction being parallel to an upper surface of the semiconductor part, the third direction being orthogonal to the first and second directions;
forming a first semiconductor part in a part of the semiconductor part not covered with the electrode and in a part of the semiconductor part that is covered with the electrode and contacts the part of the semiconductor part not covered with the electrode, the first semiconductor part being of a first conductivity type, the forming of the first semiconductor part including using the electrode as a mask to ion-implant an impurity from a direction tilted with respect to the third direction;
forming a first mask on the structure body, the first mask covering one part of the first semiconductor part, the one part not being covered with the electrode, the one part contacting a part of the semiconductor part covered with the second electrode part;
forming a second semiconductor part in a portion of the first semiconductor part by using the first mask and the electrode as a mask to ion-implant an impurity, the second semiconductor part being of a second conductivity type;
removing the first mask; and
forming a contact connected to the one part.

2. The method according to claim 1, further comprising, after the removing of the first mask, and before the forming of the contact:
forming a second mask on the structure body, the second mask covering the second semiconductor part, the second mask not covering the one part; and
forming a third semiconductor part in the one part by using the second mask and the electrode as a mask to ion-implant an impurity, the third semiconductor part being of the first conductivity type, the third semiconductor part having a higher effective impurity concentration than the first semiconductor part.

3. The method according to claim 2, wherein
the third semiconductor part contacts a part of the first semiconductor part positioned in a region directly under the sidewall, and
the third semiconductor part is separated from a part of the first semiconductor part positioned in a region directly under the first electrode part.

4. The method according to claim 1, further comprising:
after the forming of the electrode and before the forming of the first semiconductor part, forming a third mask on the structure body, the third mask not covering the semiconductor part; and
removing the third mask after the forming of the first semiconductor part and before the forming of the first mask,
the third mask also being used as the mask used in the forming of the first semiconductor part.

5. The method according to claim 1, wherein
the semiconductor part is of the first conductivity type when the forming of the electrode is performed.

6. The method according to claim 1, wherein
the second semiconductor part is partitioned into two regions by a part of the first semiconductor part positioned in the region directly under the first electrode part.

7. The method according to claim 6, wherein
the electrode is a gate electrode,
the two regions are a source region and a drain region, and
the second electrode part is located at the source region side.

8. A semiconductor device, comprising:
a first insulating film;
a first semiconductor part located on the first insulating film, the first semiconductor part being of a first conductivity type, the first semiconductor part including
a first part extending in a first direction, and
a second part extending from the first part in a second direction, the second direction crossing the first direction;
a second semiconductor part located on the first insulating film, the second semiconductor part being of a second conductivity type, the second semiconductor part contacting the first semiconductor part, the second semiconductor part being partitioned into two regions by the first semiconductor part;
a third semiconductor part located on the first insulating film, the third semiconductor part being of the first conductivity type, the third semiconductor part having a higher effective impurity concentration than the first semiconductor part, the third semiconductor part contacting the second part of the first semiconductor part, the third semiconductor part being separated from the first part of the first semiconductor part;
a second insulating film located on the first insulating film, the second insulating film surrounding a semiconductor part when viewed from above, the semiconductor part including the first, second, and third semiconductor parts;
an electrode including
a first electrode part located in a region directly above the first part,
a second electrode part, and
a sidewall located in a region directly above the second part, the sidewall being insulative and being located at a periphery of a conductive part that includes the first electrode part and the second electrode part when viewed along a third direction, the third direction being orthogonal to the first and second directions; and
a contact connected to the third semiconductor part.

9. The device according to claim 8, wherein
the electrode is a gate electrode,
the two regions are a source region and a drain region, and
the third semiconductor part is located at the source region side and contacts the source region.

10. The device according to claim 8, wherein
the first conductivity type is a p-type, and
the second conductivity type is an n-type.

11. The device according to claim 8, further comprising:
a semiconductor substrate,
the first insulating film being located on the semiconductor substrate.
